(19) United States
(12) Patent Application Publication
(10) Pub. No.: US 2025/0359395 A1
(43) Pub. Date: Nov. 20, 2025

(54) METHOD FOR FORMING AN EPITAXIAL STRUCTURE

(71) Applicant: PlayNitride Display Co., Ltd., MiaoLi County (TW)

(72) Inventors: Hsin-Chiao Fang, MiaoLi County (TW); Shen-Jie Wang, MiaoLi County (TW); Yen-Lin Lai, MiaoLi County (TW)

(73) Assignee: PlayNitride Display Co., Ltd., MiaoLi County (TW)

(21) Appl. No.: 19/287,771

(22) Filed: Jul. 31, 2025

Related U.S. Application Data
(62) Division of application No. 17/994,016, filed on Nov. 25, 2022.

(30) Foreign Application Priority Data
Oct. 12, 2022 (TW) 111138536
Oct. 12, 2022 (TW) 111138555

(51) Int. Cl. H10H 20/01; H10H 20/812; H10H 20/824; H10H 20/83

(52) U.S. Cl. CPC H10H 20/013; H10H 20/812; H10H 20/824; H10H 20/83

(57) ABSTRACT

An epitaxial structure includes a first epitaxial layer, a second epitaxial layer, and an interface treatment layer. The second epitaxial layer is disposed on the first epitaxial layer. The interface treatment layer is located between the first epitaxial layer and the second epitaxial layer and is in contact with the first epitaxial layer and the second epitaxial layer. The first epitaxial layer, the second epitaxial layer, and the interface treatment layer include the same material. An image contrast ratio of a transmission electron microscope (TEM) of the interface treatment layer to the first epitaxial layer and an image contrast ratio of a TEM of the interface treatment layer to the second epitaxial layer are both greater than 1.005. A method for forming an epitaxial structure is also provided.

### CROSS-REFERENCE TO RELATED APPLICATION

This application is a divisional application of U.S. application Ser. No. 17/994,016, filed on Nov. 25, 2022, which claims the priority benefit of Taiwan application serial no. 111138555, filed on Oct. 12, 2022, and Taiwan application serial no. 111138536, filed on Oct. 12, 2022. The entirety of each of the above-mentioned patent applications is hereby incorporated by reference herein and made a part of this specification.

### BACKGROUND

### Technical Field

The disclosure relates to an epitaxial structure and a method for forming the same.

### Description of Related Art

A light emitting diode (LED) has a self-luminous display characteristic. Compared with an organic LED (OLED) technology, which is also a self-luminous display, the LED not only has a high efficiency, a long life, but also a relatively stable material that is not easily affected by the environment. Therefore, the LED is expected to surpass the OLED display technology and become the mainstream of future display technology. However, the current LED still faces many technical challenges such as an efficiency droop effect.

Specifically, when the LED is within an operating range of a current density, it corresponds to a peak of an external quantum efficiency (EQE). As the current density of the LED continues to increase, the external quantum efficiency decreases accordingly. The phenomenon is the efficiency droop effect of the LED. Generally speaking, in order to enable the LED to emit light in high brightness, the current density of the LED is often in the operating range of a relatively high current density. However, with the miniaturization of the LED, a micro-LED is produced, and the external quantum efficiency in the operating range of the relatively high current density is degraded, so the epitaxial structure of the micro-LED plays a very important role in the way of improving the light emission efficiency of the micro-LED while still slowing down the efficiency droop effect of the LED. Since the size of the micro-LED is much smaller than the size of the conventional LED, preventing a leakage problem in the epitaxial structure is one of the urgent issues to be solved in the field.

### SUMMARY

The disclosure provides an epitaxial structure with a favorable light emission efficiency.

The disclosure provides a method for forming an epitaxial structure, which manufactures the epitaxial structure with a favorable light emission efficiency.

An epitaxial structure according to an embodiment of the disclosure includes a first epitaxial layer, a second epitaxial layer, and an interface treatment layer. The second epitaxial layer is disposed on the first epitaxial layer. The interface treatment layer is located between the first epitaxial layer and the second epitaxial layer and is in contact with the first epitaxial layer and the second epitaxial layer. The first epitaxial layer, the second epitaxial layer, and the interface treatment layer include the same material. An image contrast ratio of a transmission electron microscope (TEM) of the interface treatment layer to the first epitaxial layer and an image contrast ratio of a TEM of the interface treatment layer to the second epitaxial layer are both greater than 1.005.

A method for forming an epitaxial structure according to an embodiment of the disclosure includes: forming a base layer; forming a first epitaxial layer on the base layer at a first temperature; increasing an ambient temperature to form an interface treatment layer on the first epitaxial layer; and forming a second epitaxial layer on the interface treatment layer at a second temperature. The second temperature is greater than the first temperature. The first epitaxial layer, the second epitaxial layer, and the interface treatment layer include the same material. An image contrast ratio of a TEM of the interface treatment layer to the first epitaxial layer and an image contrast ratio of a TEM of the interface treatment layer to the second epitaxial layer are both greater than 1.005.

Based on the above, in the epitaxial structure and the method for forming the same according to the embodiments of the disclosure, the interface treatment layer is located between the first epitaxial layer and the second epitaxial layer, and the image contrast ratio of the TEM of the interface treatment layer to the first epitaxial layer and the image contrast ratio of the TEM of the interface treatment layer to the second epitaxial layer are both greater than 1.005, so the second epitaxial layer may be grown at a higher temperature and the leakage current of the epitaxial structure may be reduced. Therefore, the epitaxial structure and the method for forming the epitaxial structure according to the embodiments of the disclosure may enable the epitaxial structure to have a favorable light emission efficiency.

In order to make the above-mentioned features and advantages of the disclosure easier to understand, the following specific embodiments are given and described in details with the accompanying drawings as follows.

### BRIEF DESCRIPTION OF THE DRAWING

FIG. 1 is a schematic cross-sectional diagram of an epitaxial structure according to an embodiment of the disclosure.

FIG. 2 is a flow diagram of a method for forming an epitaxial structure according to an embodiment of the disclosure.

FIG. 3 is a schematic cross-sectional diagram of a manufacturing process of an epitaxial structure according to an embodiment of the disclosure.

FIG. 4 is a partial image diagram of a TEM of the epitaxial structure of FIG. 1.

FIG. 5 is a distribution diagram of a partial signal intensity of a TEM of the epitaxial structure of FIG. 1 relative to a depth of the epitaxial structure.

FIG. 6 is a schematic cross-sectional diagram of an epitaxial structure according to another embodiment of the disclosure.

### DESCRIPTION OF THE EMBODIMENTS

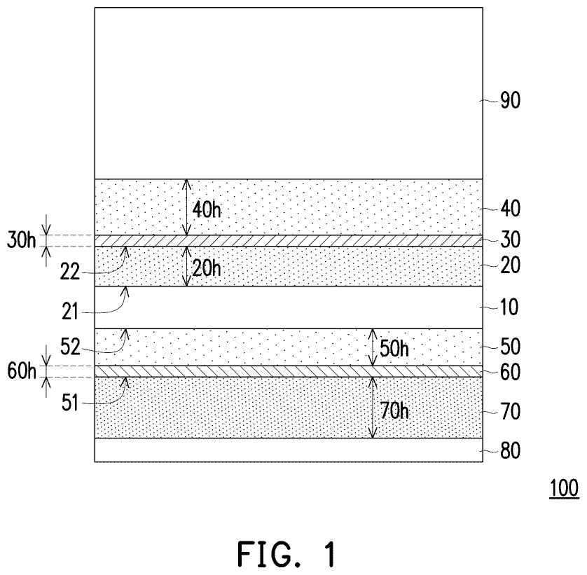

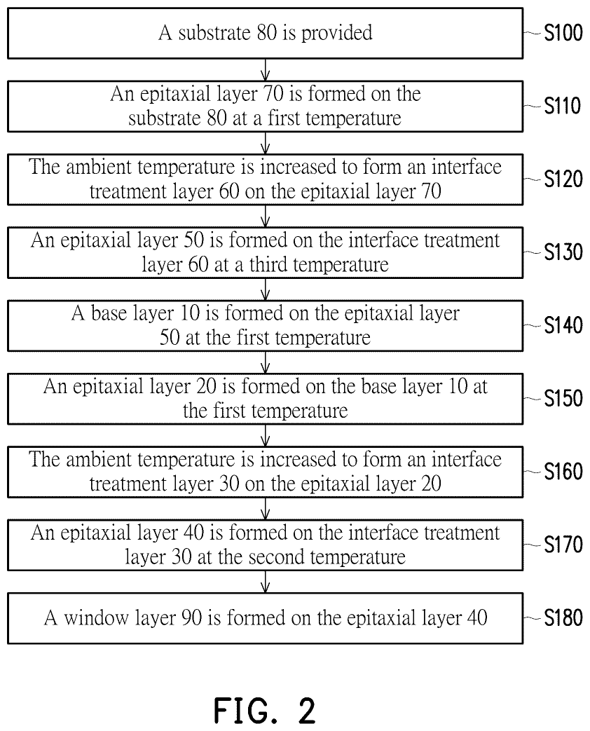

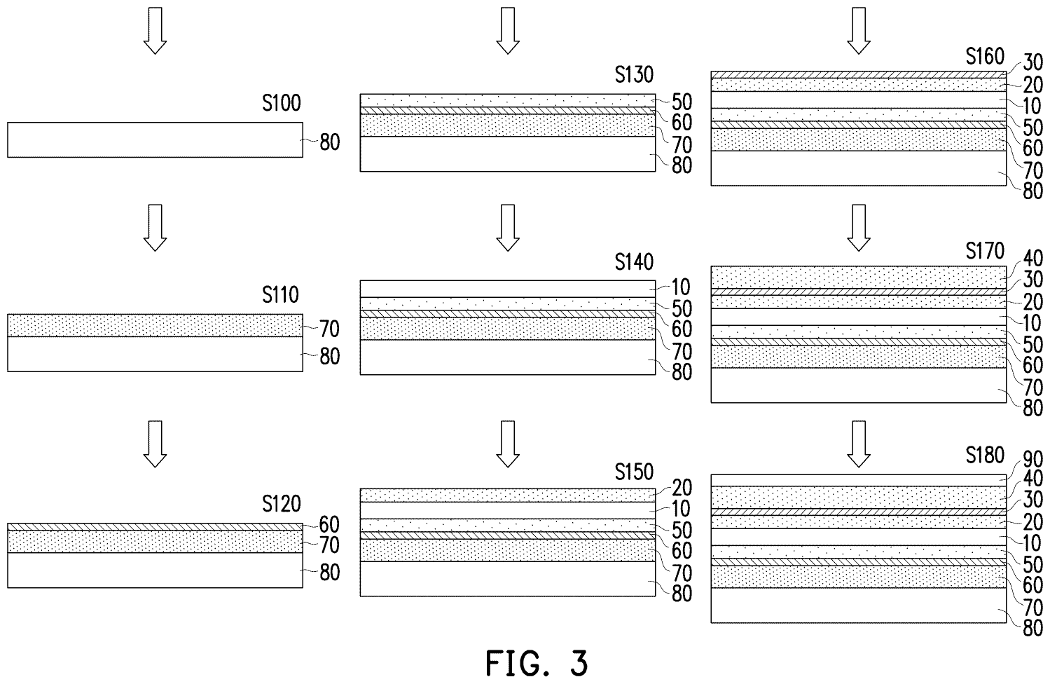

FIG. 1 is a schematic cross-sectional diagram of an epitaxial structure according to an embodiment of the disclosure, and FIGS. 2 and 3 are a flow diagram of a method for forming an epitaxial structure and a schematic cross-sectional diagram of a manufacturing process of an epitaxial structure according to an embodiment of the disclosure.

Referring to FIG. 1 to FIG. 3 at the same time, the method for forming an epitaxial structure 100 of the embodiment includes the following. In step S100 of the embodiment, a substrate 80 is provided. The material of the substrate 80 is, for example, a neutral gallium arsenide substrate or an n-type gallium arsenide substrate. In another embodiment of the disclosure, the material of the substrate 80 is, for example, an aluminum oxide (a sapphire) substrate. Alternatively, in another embodiment, the material of the substrate 80 includes, for example, a Group II-VI material (e.g., an n-type zinc selenide), but is not limited hereto.

In step S110, an epitaxial layer 70 is formed on the substrate 80. The epitaxial layer 70 may be formed at a first temperature.

In step 120, an ambient temperature is increased to form an interface treatment layer 60 on the epitaxial layer 70. For example, the epitaxial layer 70 is grown by a metal oxide chemical vapor deposition method. Before continuing to grow an epitaxial layer 50, the supply of source material gas to the epitaxial layer 70 may be stopped, and the ambient temperature inside a metal oxide chemical vapor deposition cavity is simply increased. For example, the first temperature is increased to a third temperature, and a difference between the third temperature and the first temperature exceeds 30 degrees. When the temperature is increased, a part of an indium on a surface of the epitaxial layer 70 will dissipate into the cavity due to an increase in the temperature, so that the surface of the epitaxial layer 70 forms the interface treatment layer 60 with a lower indium content.

In the embodiment, a thickness 60h of the interface treatment layer 60 is, for example, within the range of 1 nm to 10 nm, e.g., within the range of 1 nm to 5 nm, or within the range of 1 nm to 2 nm.

In step S130, the epitaxial layer 50 is formed on the interface treatment layer 60 at the third temperature. That is to say, the interface treatment layer 60 is disposed between the epitaxial layer 70 and the epitaxial layer 50 and is in contact with the epitaxial layer 70 and the epitaxial layer 50. An indium content of the epitaxial layer 50 is greater than an indium content of the interface treatment layer 60. A ratio of a thickness of the epitaxial layer 50 to a thickness of the interface treatment layer 60 and a ratio of a thickness of the epitaxial layer 70 to a thickness of the interface treatment layer 60 are, for example, greater than 50, respectively. In another embodiment, at least one of the epitaxial layer 50 and the epitaxial layer 70 may be formed at the third temperature. For example, the epitaxial layer 70 may be formed at the third temperature. That is to say, in another embodiment, the sequence for forming the epitaxial layer 70 and the interface treatment layer 60 may be changed. For example, when the ambient temperature above-mentioned is increased before forming the epitaxial layer 70, the interface treatment layer 60 may appear between the substrate 80 and the epitaxial layer 70. Moreover, in such an embodiment, other process conditions of the epitaxial layer 50 and the epitaxial layer 70 may be the same or different.

In the embodiment, the epitaxial layer 70, the interface treatment layer 60, and the epitaxial layer 50 are, for example, phosphorus-containing compound layers. Alternatively, in another embodiment, the epitaxial layer 70, the interface treatment layer 60, and the epitaxial layer 50 are, for example, n-type semiconductor layers, and the material thereof includes, for example, a Group III-V material (e.g., an n-type AlGaAs, an n-type gallium arsenide phosphorus, an n-type aluminum gallium indium phosphide, an n-type aluminum gallium phosphide, an n-type indium gallium nitride, an n-type aluminum nitride, an n-type indium nitride, an n-type aluminum gallium nitride, an n-type aluminum indium gallium nitride, an n-type gallium nitride, or an n-type GaAs). Alternatively, in another embodiment, the epitaxial layer 70, the interface treatment layer 60, and the epitaxial layer 50 include, for example, the Group II-VI material (e.g., the n-type zinc selenide), but are not limited hereto.

In the embodiment, the epitaxial layer 70, the interface treatment layer 60, and the epitaxial layer 50 may have different doping concentrations. For example, the doping concentration of the epitaxial layer 70 or the epitaxial layer 50 is greater than the doping concentration of the interface treatment layer 60. Alternatively, in other embodiments, the doping concentration of the epitaxial layer 70 or the epitaxial layer 50 is lower than or equal to the doping concentration of the interface treatment layer 60.

In the embodiment, the epitaxial layer 70 is, for example, doped with a silicon or a tellurium. Alternatively, in another embodiment, the epitaxial layer 70 is, for example, doped with a Group IV element, a Group VI element, or a combination thereof, but is not limited hereto.

In the embodiment, the epitaxial layer 50 is an inactive doping layer. The epitaxial layer 70 is doped with the silicon or the tellurium. When the first temperature is increased to the third temperature, the silicon or the tellurium diffuses into the epitaxial layer 50.

In step S140, a base layer 10 is formed on the epitaxial layer 50 at the first temperature. The base layer 10 is, for example, an active layer or a light emitting layer. The structure of the base layer 10 is, for example, a quantum well structure or a multiple-quantum wells (MQWs) structure. The epitaxial layer 70 and the epitaxial layer 50 are, for example, a cladding layer and a spacer layer, respectively. When the dopants of the epitaxial layer 70 diffuse into the epitaxial layer 50, the epitaxial layer 50 may act as a barrier layer, preventing the dopant from further diffusing to the base layer 10.

In another embodiment of the disclosure, the material of the base layer 10 may be a semiconductor material of a gallium phosphide system, and the molecular formula is (AlₓGa₁₋ₓ)_{1-y}In_{y}P, where 0≤x≤1 and 0<y<1. In some conventional embodiments where the base layer 10 is the light emitting layer, the base layer 10 may be a gallium indium phosphide (GaInP) material.

In step S150, an epitaxial layer 20 is formed on the base layer 10 at the first temperature. In the embodiment, the epitaxial layer 20 and the base layer 10 are both formed at the first temperature, so that when the base layer 10 is the active layer or the light emitting layer, a favorable crystal quality may be obtained, and thermal damage to the quantum well structure caused by a change in the temperature may be prevented. In another embodiment, the temperature for forming the epitaxial layer 20 may also be different from the temperature for forming the epitaxial layer 70, and the temperature for forming the base layer 10 may also be different from the temperature for forming the epitaxial layer 50 and the epitaxial layer 70. For example, when the base layer 10 is used as the active layer or the light emitting layer, the temperature for forming the base layer 10 is preferably lower than the temperature for forming the epitaxial layer 50 and the epitaxial layer 70, respectively.

In step S160, the ambient temperature is increased to form an interface treatment layer 30 on the epitaxial layer 20. For example, the epitaxial layer 20 is grown by the metal oxide chemical vapor deposition method. Before continuing to grow an epitaxial layer 40, the supply of source material gas to the epitaxial layer 20 may be stopped, and the ambient temperature inside the metal oxide chemical vapor deposition cavity is simply increased. For example, the first temperature is increased to a second temperature, and the difference between the second temperature and the first temperature exceeds 30 degrees. When the temperature is increased, a part of an indium on a surface of the epitaxial layer 20 will dissipate into the cavity due to an increase in the temperature, so that the surface of the epitaxial layer 20 forms the interface treatment layer 30 with a lower indium content.

In the embodiment, a thickness 30h of the interface treatment layer 30 is, for example, within the range of 1 nm to 10 nm, e.g., within the range of 1 nm to 5 nm, or within the range of 1 nm to 2 nm.

In step S170, the epitaxial layer 40 is formed on the interface treatment layer 30 at the second temperature. That is to say, the interface treatment layer 30 is disposed between the epitaxial layer 20 and the epitaxial layer 40 and is in contact with the epitaxial layer 20 and the epitaxial layer 40. An indium content of the epitaxial layer 40 is greater than an indium content of the interface treatment layer 30. A ratio of a thickness of the epitaxial layer 20 to a thickness of the interface treatment layer 30 and a ratio of a thickness of the epitaxial layer 40 to a thickness of the interface treatment layer 30 are, for example, greater than 50, respectively.

In the embodiment, the epitaxial layer 20, the interface treatment layer 30, and the epitaxial layer 40 are, for example, the phosphorus-containing compound layer. The doping type of the epitaxial layer 20, the interface treatment layer 30, and the epitaxial layer 40 are different from the doping type of the epitaxial layer 50, the interface treatment layer 60, and the epitaxial layer 70. In one embodiment, the epitaxial layer 20, the interface treatment layer 30, and the epitaxial layer 40 are, for example, a p-type semiconductor layer, and the material thereof includes, for example, the Group III-V material (e.g., a p-type aluminum gallium arsenide, a p-type Gallium Arsenide Phosphide, a p-type Aluminum Gallium Indium Phosphide, a p-type Aluminum Gallium Phosphide, a p-type Indium Gallium Nitride, a p-type Aluminum Nitride, a p-type Indium Nitride, a p-type Aluminum Gallium Nitride, a p-type Nitride Aluminum indium gallium, a p-type gallium nitride, or a p-type gallium phosphide. Alternatively, in another embodiment, the epitaxial layer 20, the interface treatment layer 30, and the epitaxial layer 40 include, for example, the Group II-VI material (e.g., a p-type zinc selenide), but are not limited thereto.

In the embodiment, the epitaxial layer 20, the interface treatment layer 30, and the epitaxial layer 40 may have different doping concentrations, for example, the doping concentration of the epitaxial layer 20 or the epitaxial layer 40 is greater than the doping concentration of the interface treatment layer 30. Alternatively, in other embodiments, the doping concentration of the epitaxial layer 20 or the epitaxial layer 40 is lower than or equal to the doping concentration of the interface treatment layer 30.

In the embodiment, the epitaxial layer 40 is, for example, doped with a magnesium, a zinc, a carbon, a selenium, or a beryllium. Alternatively, in another embodiment, the epitaxial layer 20 is, for example, doped with a Group II element, the Group IV element, the Group VI element, or a combination thereof, but is not limited thereto.

In the embodiment, the epitaxial layer 20 is the inactive doping layer. The epitaxial layer 40 is doped with the magnesium, the zinc, the carbon, the selenium, or the beryllium. When the first temperature is increased to the second temperature, the magnesium, the zinc, the carbon, the selenium, or the beryllium diffuses into the epitaxial layer 20, whereas the epitaxial layer 20 can prevent the magnesium, the zinc, the carbon, the selenium, or the beryllium from diffusing into the base layer 10 as possible.

In the embodiment, the second temperature is equal to the third temperature. Alternatively, in another embodiment, the second temperature is greater than the third temperature. Alternatively, in yet another embodiment, the second temperature is less than the third temperature. Both the second temperature and the third temperature are greater than the first temperature. Since the epitaxial layer 40 and the epitaxial layer 50 are formed at a relatively high temperature, the leakage current of the epitaxial structure is reduced.

In the embodiment, a composition of the epitaxial layer 20, the interface treatment layer 30, and the epitaxial layer 40 is, for example, AlᵤGaᵥIn_{w}P, and a value of a ratio of the above composition expressed according to the atomic number of each element is 13u+31v+49w. The value of the interface treatment layer 30 is lower than the value of the epitaxial layer 20 and the epitaxial layer 40. In other words, the indium content of the interface treatment layer 30 is reduced because the indium with a larger atomic number in the interface treatment layer 30 is dissipated into the cavity, so the value above is also lower than the value of the epitaxial layer 20 and the epitaxial layer 40.

In the embodiment, a carrier provided by the epitaxial layer 50 and a carrier provided by the epitaxial layer 20 are combined in the base layer 10 and emit light, which includes (but is not limited to) a red light (a wavelength range of about 620 nm to 750 nm), an ultraviolet light (a wavelength range of about 1 nm to 380 nm), a purple light (a wavelength range of about 380 nm to 450 nm), a blue light (a wavelength range of about 450 nm to 495 nm), a green light (a wavelength range of about 495 nm to 570 nm), a yellow light (a wavelength range of about 570 nm to 590 nm), or an orange light (a wavelength range about 590 nm to 620 nm).

In step S180, a window layer 90 is formed on the epitaxial layer 40. The window layer 90 is used as a light extraction layer. In the embodiment, the material of the window layer 90 is the p-type gallium phosphide.

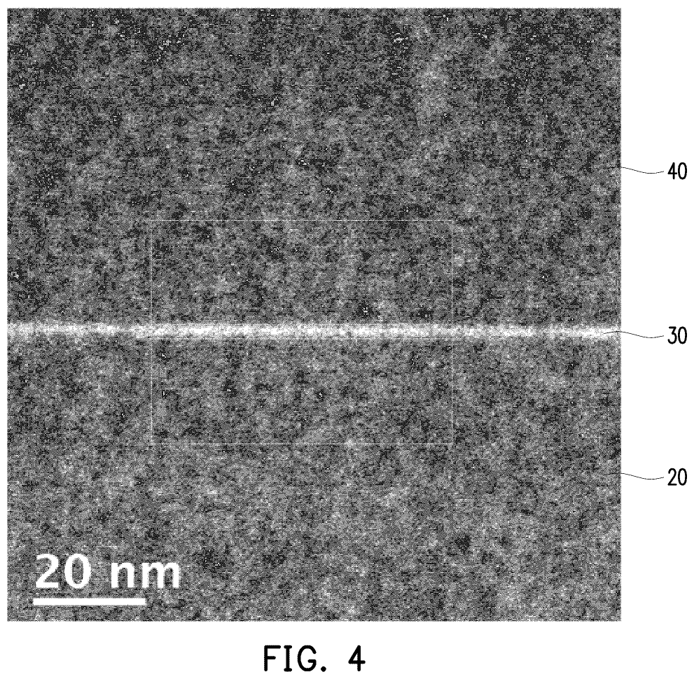

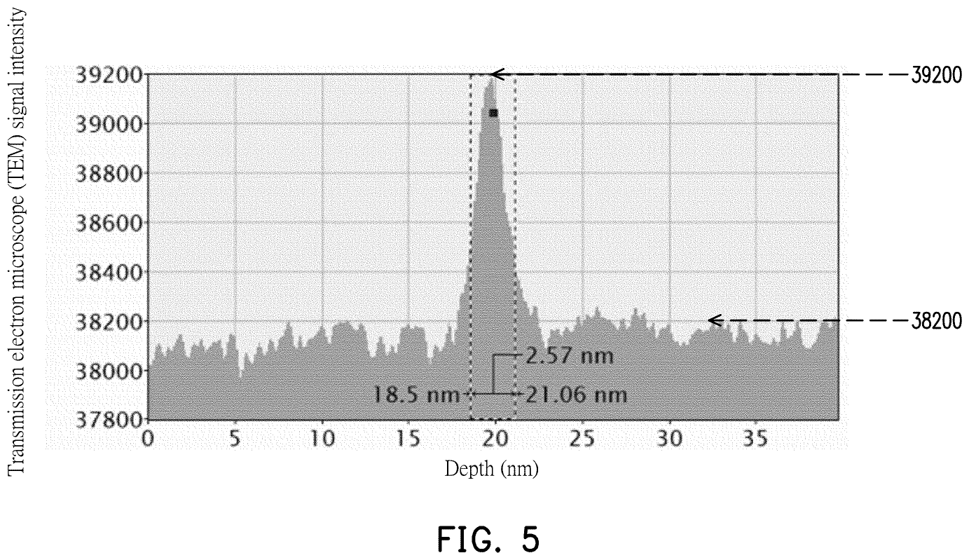

FIG. 4 is a partial image diagram of a TEM of the epitaxial structure of FIG. 1, and FIG. 5 is a distribution diagram of a partial signal intensity of a TEM of the epitaxial structure of FIG. 1 relative to a depth of the epitaxial structure.

Referring to FIG. 4 and FIG. 5 at the same time, in the embodiment, since the indium content of the interface treatment layer 30 is lower than the indium content of the epitaxial layer 20 and the epitaxial layer 40, an electron transmittance of the interface treatment layer 30 to the TEM is greater than an electron transmittance of the epitaxial layer 20 and the epitaxial layer 40 to the TEM. Referring to FIG. 4, the image signal intensity of the interface treatment layer 30 is greater (i.e., the image brightness is greater), while the image signal intensity of the epitaxial layer 20 and the epitaxial layer 40 is lower (i.e., the image brightness is lower). The reason is that the content of the indium with the large atomic number in the interface treatment layer 30 is reduced, so an electron beam is easier to penetrate through the interface treatment layer 30 and be detected.

In the embodiment, an image contrast ratio of the TEM of the interface treatment layer 30 to the epitaxial layer 20 and an image contrast ratio of the TEM of the interface treatment layer 30 to the epitaxial layer 40 are both greater than 1.005.

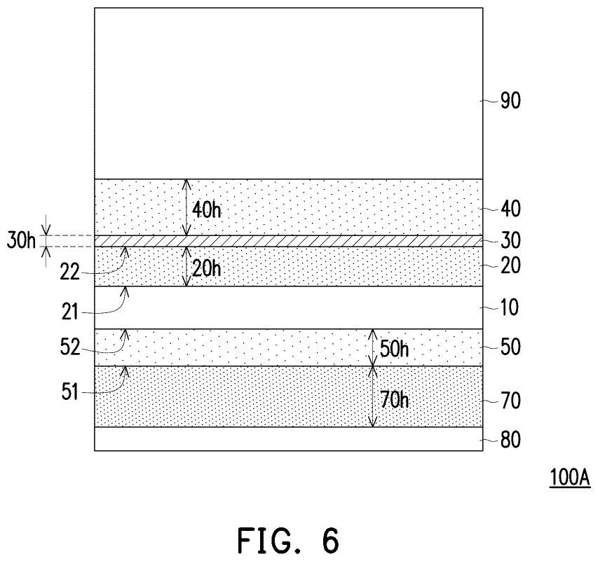

FIG. 6 is a schematic cross-sectional diagram of an epitaxial structure according to another embodiment of the disclosure.

Referring to FIG. 2 and FIG. 6 at the same time, an epitaxial structure 100A of the embodiment is similar to the epitaxial structure 100 of FIG. 1, and the difference between the two is that the epitaxial structure 100A of the embodiment does not have the interface treatment layer 60 of FIG. 1, that is, in the embodiment, step S120 in FIG. 2 may be omitted, and the epitaxial layer 50 may be formed on the epitaxial layer 70 at the first temperature. In the embodiment, a sum of a thickness 20h of the epitaxial layer 20 and a thickness 40h of the epitaxial layer 40 is greater than a sum of a thickness 50h of the epitaxial layer 50 and a thickness 70h of the epitaxial layer 70. In other words, in the embodiment, the interface treatment layer 30 exists only on one side of the epitaxial layer 20 and the epitaxial layer 40 with a greater thickness, but the epitaxial layer 50 and the epitaxial layer 70 with a lesser thickness do not include the interface treatment layer. In the epitaxial structure 100A, if only one side of the semiconductor layer (e.g., one of the p-type or n-type) is subjected to heating treatment, it is preferable to select the side with the greater thickness (i.e., a higher percentage of the sidewall surface area) in order to obtain a favorable protection effect of the leakage current, so as to improve the light emission efficiency of the micro-LED. However, the disclosure does not limit the above-mentioned selective heating treatment to only between the epitaxial layer 20 and the epitaxial layer 40, and in other embodiments not illustrated, the interface treatment layer 60 may also only exist between the epitaxial layer 50 and the epitaxial layer 70, and the epitaxial layer 40 is directly formed on the epitaxial layer 20.

To sum up, the interface treatment layer of the embodiment of the disclosure is located between the first epitaxial layer and the second epitaxial layer, and the image contrast ratio of the TEM of the interface treatment layer to the first epitaxial layer and the image contrast ratio of the TEM of the interface treatment layer to the second epitaxial layer are both greater than 1.005, so the second epitaxial layer may be grown at a higher temperature and the leakage current of the epitaxial structure may be reduced. Therefore, the epitaxial structure and the method for forming the epitaxial structure according to the embodiments of the disclosure may enable the epitaxial structure to have a favorable light emission efficiency.

Although the disclosure has been described with reference to the embodiments above, the embodiments are not intended to limit the disclosure. Any person skilled in the art may make some changes and modifications without departing from the spirit and scope of the disclosure. Therefore, the scope of the disclosure will be defined in the appended claims.

What is claimed is:

1. A method for forming an epitaxial structure, comprising:
forming a base layer;
forming a first epitaxial layer on the base layer at a first temperature;
increasing an ambient temperature to form an interface treatment layer on the first epitaxial layer; and
forming a second epitaxial layer on the interface treatment layer at a second temperature, wherein the second temperature is greater than the first temperature, the first epitaxial layer, the second epitaxial layer, and the interface treatment layer comprise the same material, and an image contrast ratio of a transmission electron microscope (TEM) of the interface treatment layer to the first epitaxial layer and an image contrast ratio of a transmission electron microscope (TEM) of the interface treatment layer to the second epitaxial layer are both greater than 1.005.

2. The method for forming the epitaxial structure according to claim 1, wherein the first epitaxial layer, the second epitaxial layer, and the interface treatment layer comprise an indium, and an indium concentration of the first epitaxial layer and the second epitaxial layer is greater than an indium concentration of the interface treatment layer.

3. The method for forming the epitaxial structure according to claim 1, wherein an electron transmittance of the interface treatment layer to the transmission electron microscope (TEM) is greater than an electron transmittance of the first epitaxial layer and the second epitaxial layer to the transmission electron microscope (TEM).

4. The method for forming the epitaxial structure according to claim 1, wherein the base layer is an active layer, and before forming the base layer, the method for forming the epitaxial structure further comprises:
sequentially forming another second epitaxial layer and another first epitaxial layer on a substrate, wherein at least one of the another second epitaxial layer and the another first epitaxial layer is formed at a third temperature greater than the first temperature.
